(19) United States
(12) Patent Application Publication
(10) Pub. No.: US 2007/0077774 A1
(43) Pub. Date: Apr. 5, 2007

(54) Method for manufacturing a semiconductor device having a stepped contact hole

(75) Inventor: Kazuyoshi Yoshida, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/529,328

(22) Filed: Sep. 29, 2006

(30) Foreign Application Priority Data
Sep. 30, 2005 (JP) 2005-286728

(51) Int. Cl. H01L 21/31

(52) U.S. Cl. 438/758

(57) ABSTRACT

A process for forming a stepped contact hole includes: dry-etching a portion of a silicon oxide film using a mixed gas including carbon-rich fluorocarbon gas to form a first contact hole, forming a specific film on the sidewall of the first contact hole; dry-etching the remaining portion of the silicon oxide film at the bottom of the first contact hole by using the specific film as a mask to form a second contact hole extending from the first contact hole; and removing the specific film.

### BACKGROUND OF THE INVENTION

(a) Field of the Invention

The present invention relates to a method for manufacturing a semiconductor device having a stepped contact hole and, more particularly, to an improvement in forming a contact hole having a stepped structure including a top portion and a bottom portion having different diameters in a semiconductor device.

(b) Description of the Related Art

In a semiconductor device such as a DRAM device, an anisotropic etching process is generally used for forming a contact hole exposing the top of an underlying contact plug in contact with a diffused region of a semiconductor substrate. The contact hole to be formed by the anisotropic etching may be desired to have a stepped structure including a top portion having a large diameter and a bottom portion having a small diameter. The purpose for forming the small-diameter bottom portion is to allow the bottom portion to pass through a gap between adjacent interconnect lines, whereas the purpose for forming the large-diameter top portion is to assure a larger alignment margin between the contact plug filling the contact hole and an overlying interconnect or electrode.

An example of the stepped contact hole is described in Patent Publication JP-1992-125925A. FIGS. 3A to 3E consecutively show steps of the process described in the publication. As shown in FIG. 3A, a SiO₂ film (not shown) is formed on a surface of a semiconductor (silicon) substrate 31, and an interlevel dielectric film 32 is formed thereon. A photoresist mask pattern 33 is formed on the dielectric film 32. The dielectric film 33 is then etched in a chamber by an anisotropic dry etching technique using an etching gas including CF₄ and a photoresist mask pattern 33 as an etching mask, as shown in FIG. 3B, to form first contact holes 35 having a specified depth smaller than the thickness of the dielectric film 32.

Thereafter, the etching process is changed into a deposition process in the chamber by raising the internal gas pressure and the gas flow rate while reducing the applied RF power, thereby forming a specific deposited film 34 including carbon and hydrogen over the entire area of the semiconductor substrate 31, as shown in FIG. 3C.

Subsequently, the process condition is again changed into the original anisotropic dry etching condition, thereby etching the deposited film 34 by another anisotropic etching process on top of the photoresist mask 33 and bottom of the first contact holes 35. The anisotropic etching process further etches the bottom of the contact holes 35 configured by the remaining dielectric film 32 to form second contact holes 36 exposing therethrough a portion of the surface of the semiconductor substrate 31, and then etches the deposited film 34 remaining on the inner wall of the first contact holes 35 and the photoresist mask 33. Thus, stepped contact holes having a top portion configured by the first contact holes 35 and a bottom portion configured by the second contact holes 36 are formed to penetrate the dielectric film 32.

The process described in the patent publication is such that the first contact holes 35 are formed by using an etching gas including CF₄, the inner wall of the first contact holes 35 is covered by the deposited film 34, the bottom of the first contact holes 35 is then etched by using the deposited film 34 as an etching mask to form the second contact holes 36 having a diameter smaller than the diameter of the first contact holes 35, and then the deposited film 34 is removed from the inner wall of the first contact holes 35.

Another technique for forming the stepped contact holes is described in Patent Publication JP-1999-260755A. FIGS. 4A to 4F show consecutive steps of the process described in this publication. As shown in FIG. 4A, a conductive film 42 is formed on an underlying structure 41 including a semiconductor substrate, followed by forming a first mask pattern 43 thereon. The conductive film 42 is then etched using the first mask pattern as an etching mask, as shown in FIG. 4B, to configure interconnect lines 42a.

Subsequently, a planarizing dielectric film 44 is deposited on the interconnect lines 42a and the underlying structure 41. A second mask pattern 45 is formed on the planarizing dielectric film 44, followed by etching the planarizing dielectric film 44 by using the second mask pattern as an etching mask and a mixed gas including CHF₃, C₂HF₅ and C₄F₈ as an etching gas to thereby form contact holes 46 therein, as shown in FIG. 4E. During this etching, the mixing ratio of the etching gas is controlled to allow the resultant contact holes to have a tapered-stepped structure, wherein the contact holes 46 have a stepped structure and both the top and bottom portions have respective tapers each having a smaller-diameter bottom. Thereafter, the second mask pattern 45 is removed.

The process described in JP-1999-260755 achieves the stepped structure including top and bottom portions having different diameters in a single etching step without using a dedicated deposition step. This stepped structure is suited to the contact holes which are formed in a gap between adjacent interconnect lines and have a larger marginal area for an electric contact with respect to overlying contact plugs.

The process for forming the contact holes in the technique described in JP-1992-125925 employs an anisotropic etching step using a CF₄-containing etching gas. There is a problem in this anisotropic etching process, however, that the CF₄-containing etching gas has a smaller etch selectivity between the mask pattern 33 and the dielectric film 32, whereby the top portion of the contact holes may have an excessively larger diameter or a distorted sectional structure. This problem is especially crucial when a thin film photoresist mask is used for forming small-diameter contact holes, and thus is difficult to employ if a plurality of small-diameter contact holes are arranged at a higher density.

The process for forming the contact holes in the technique described in JP-1999-260755 employs an etching step in which deposition of the specific film is concurrently performed. This process may involve an etch stop failure during the etching step due to the concurrent deposition step, and thus it is difficult to perform a stable etching therein.

### SUMMARY OF THE INVENTION

In view of the above problems in the conventional techniques, it is an object of the present invention to provide a method for manufacturing a semiconductor device including a contact hole having a stepped structure, which is capable of etching a dielectric film with a higher etch selectivity, without involving an etch stop failure to thereby perform a stable etching.

The present invention provides a method for manufacturing a semiconductor device including: forming a dielectric film on an underlying structure including a semiconductor substrate; etching the dielectric film in a first anisotropic dry etching step using a first gas including rare gas, oxygen gas and carbon-rich gas, which is richer than CF₄ to in carbon content, and a photoresist mask as an etching mask to a specified depth of the dielectric film, to thereby form a first contact hole in the dielectric film; depositing a specific film at least within the first contact hole by using a second gas as a source gas; etching a first potion of the specific film on a bottom of the first contact hole selectively from a second portion of the specific film on a sidewall thereof in a second anisotropic dry etching step using a third gas as an etching gas, to expose the dielectric film through the bottom of the first contact hole; etching the dielectric film exposed from the bottom of the first contact hole in a third anisotropic dry etching step using a fourth gas as an etching gas and the second portion of the specific film as an etching mask, to form a second contact hole extending stepwise from the first contact hole and exposing therefrom the underlying structure; and removing the second portion of the specific film on the sidewall of the first contact hole.

In accordance with the method of the present invention, the first gas including the carbon-rich gas, which is richer than CF₄ gas in the carbon content, allows the first anisotropic dry etching step to achieve a higher etch selectivity of the dielectric with respect to the photoresist mask compared to the etch selectivity in the anisotropic etching step of the conventional process using the CF₄ gas. This provides a stable diameter for the first contact holes substantially without involving an etch stop failure in the first anisotropic dry etching step or a taper in the first contact hole.

The above and other objects, features and advantages of the present invention will be more apparent from the following description, referring to the accompanying drawings.

### BRIEF DESCRIPTION OF THE DRAWINGS

FIG. 1 is a sectional view of a semiconductor device manufactured by a method according to an embodiment of the present invention.

FIGS. 2A to 2H are sectional views of the semiconductor device of FIG. 1 in steps of fabrication thereof.

FIGS. 3A to 3E are sectional views of a conventional semiconductor device in consecutive steps fabrication thereof.

FIGS. 4A to 4F are sectional views of another semiconductor device in consecutive steps of fabrication thereof.

### PREFERRED EMBODIMENT OF THE INVENTION

Now, the present invention is more specifically described with reference to accompanying drawings.

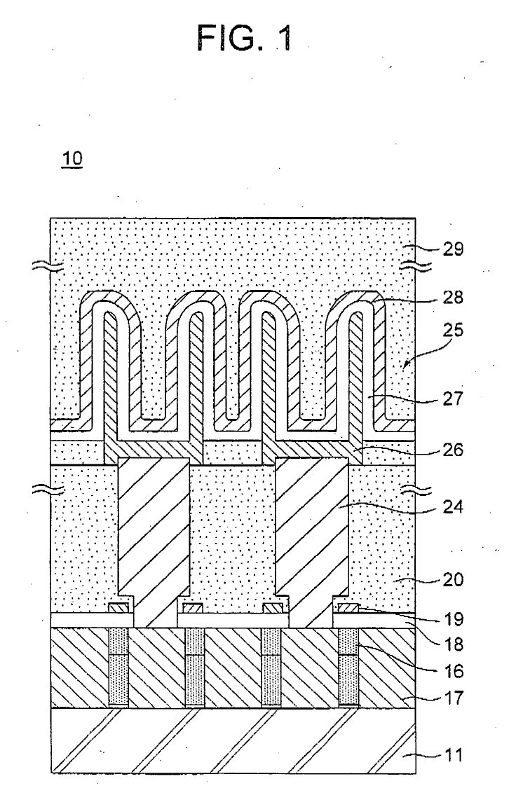

FIG. 1 shows a semiconductor device configured as a DRAM device, which is manufactured by a method according to an embodiment of the present invention. The DRAM device, generally designated by numeral 1Q, includes a semiconductor substrate 11 having diffused regions (not shown) on the surface region thereof. The diffused regions configure source/drain of cell transistors in contact with first contact plugs 17 penetrating through a first-layer dielectric film (silicon oxide film) 16. Second contact plugs 24 are in contact with top of the respective first contact plugs 17. The second contact plugs 24 penetrate through second- and third-layer dielectric films (silicon oxide films) 18, 20 and have a top in contact with bottom electrodes 26 of an overlying cell capacitors 25. The cell capacitors 25 include the bottom electrodes 26, capacitor insulation film 27 and top electrodes 28, and are embedded in a third-layer dielectric film 29.

The second contact plugs 24 extend upward from the top of the first contact plugs 17, and intersect interconnect lines 19 formed on the second-layer dielectric film 18 which overlies the first contact plugs 17. The second contact plugs 24 have a stepped structure wherein the top portion has a larger diameter and the bottom portion has a smaller diameter. The second contact plugs 24 intersect the interconnect lines 19 at the bottom portion of the second contact plugs 24 while being insulated from the interconnect lines 19.

The second contact plugs 24 are in contact with the underling first contact plugs 17 at the small-diameter bottom portion of the second contact plugs 24, and in contact with the overlying bottom electrodes 26 of the cell capacitors 25 at the large-diameter top portion of the second contact plugs 24. Both the top and bottom portions of the second contact plugs 24 have a uniform diameter within each of the portions.

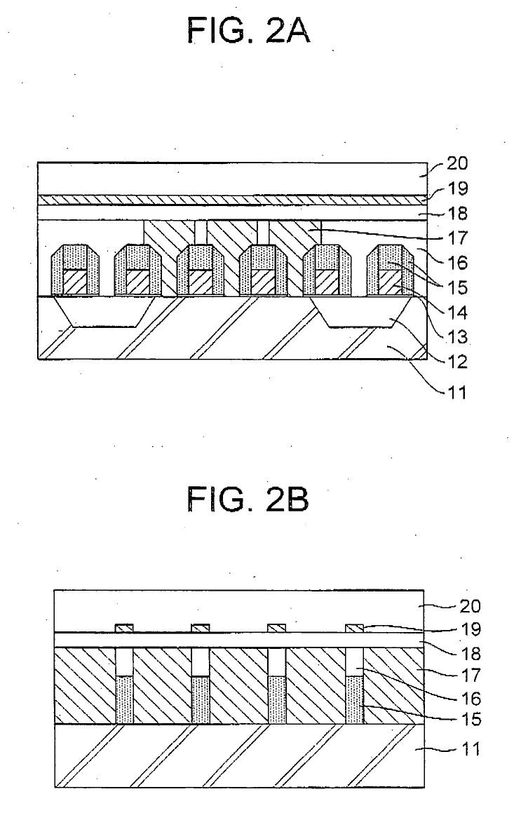

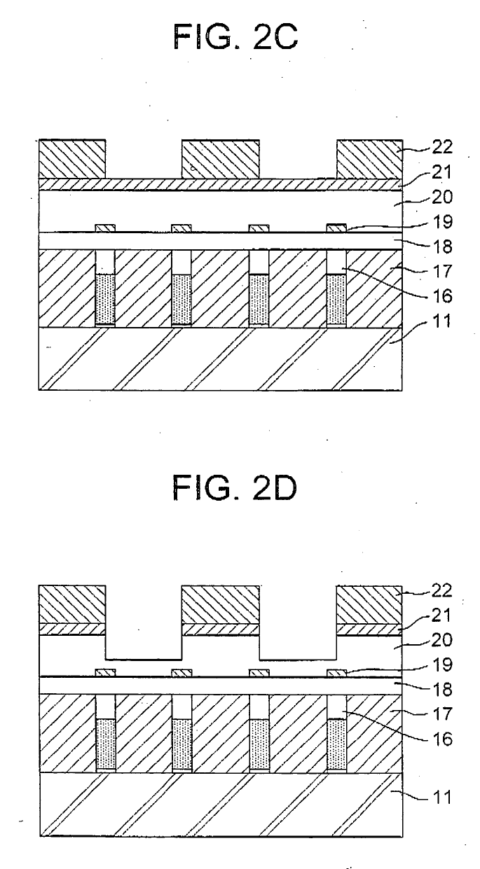

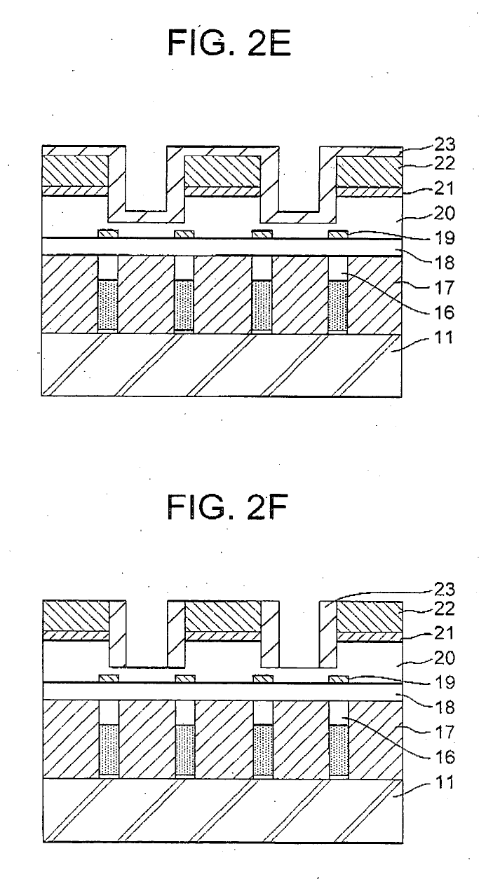

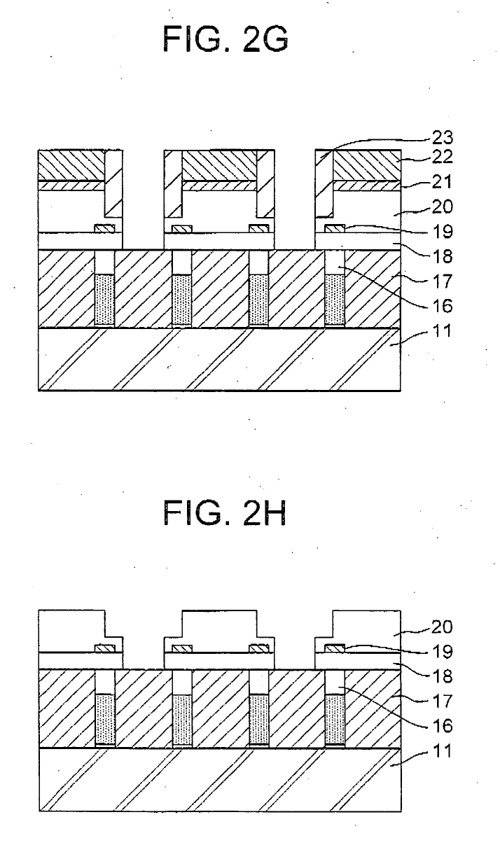

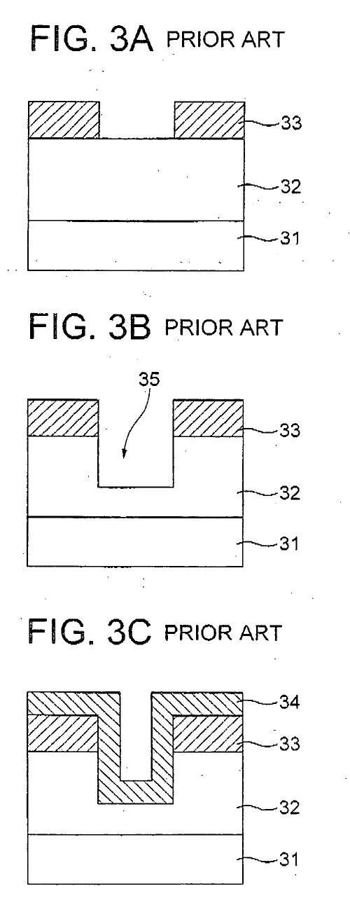

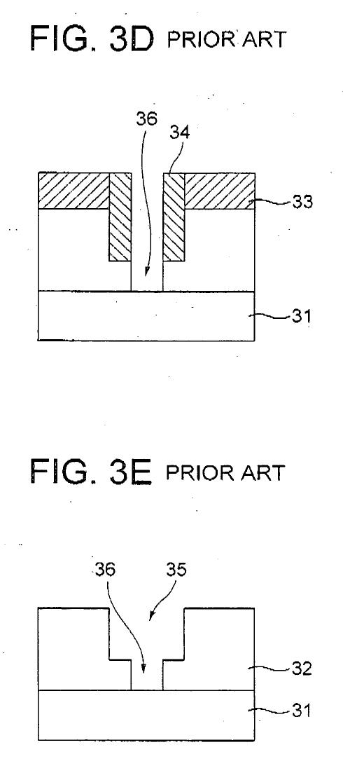

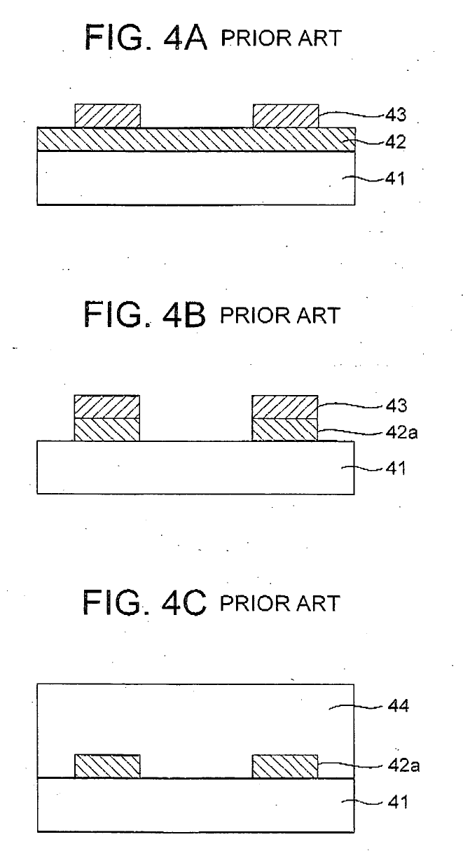

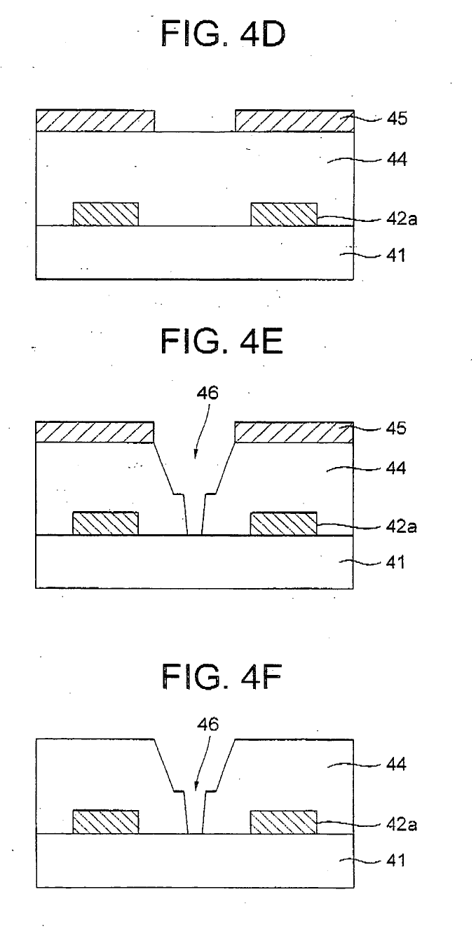

FIGS. 2A to 2H show the DRAM device 10 of FIG. 1 during steps of fabrication thereof. FIG. 2A shows a section of the DRAM device 10 in a first step taken along a direction normal to the extending direction of gate electrodes in the DRAM device, whereas FIG. 2B shows a section of the DRAM device in the first step taken along a direction parallel to the extending direction of the gate electrodes. FIGS. 2C to 2H show the section of FIG. 23 in consecutive steps succeeding to the first step of FIGS. 2A and 2B.

In the step of FIGS. 2A and 2B, a shallow-trench-isolation (STI) structure 12 is formed on a silicon substrate for isolating diffused regions (not shown) of MOSFETs, on which a gate insulation film 13 is formed. The gate electrode structure of MOSFETs includes a gate electrode 14 formed on the gate insulation film 13, and a silicon nitride film 15 covering the gate electrode 14 at the top and sidewalls of the gate electrode 14. The first-layer dielectric film 16 fills the gap between each adjacent two of the gate electrode structures and embeds the gate electrode structures.

The first contact plugs 17 penetrating through the first-level dielectric film 16 are formed between adjacent two of the gate electrode structures, by etching the first-layer dielectric film 16 in a self-alignment process to form contact holes, and then filling the resultant contact holes. The second-layer dielectric film 18, first-level interconnect lines 19 and planarizing third-layer dielectric film 20 are formed on the first-layer dielectric film 16. For example, the first-level interconnect lines 19 are 50 nm wide and 50 nm thick, and arranged at a pitch of 150 nm, and the third dielectric film 20 overlying the first-level interconnect lines is 200 nm thick.

The steps succeeding to the first step of FIGS. 2A and 2B are shown in FIGS. 2C to 2H, wherein the second contact plugs 24 are formed which connect the underlying first contact plugs 17 with the overlying conductor configuring the bottom electrodes 26 of the cell capacitors. The method of the present embodiment is applied to forming the second contact plugs 24 in the gap between adjacent two of the first-level interconnect lines 19.

After the first step, a 50-nm-thick anti-reflection film 21 made of an organic material is formed on the third-layer dielectric film 20, followed by forming thereon a 450-nm-thick photoresist film. The photoresist film is then patterned using KrF excimer laser to form a mask pattern 22 having a 150-nm-wide opening, as shown in FIG. 2C.

The mask pattern 22 is then used as an etching mask for etching the anti-reflection film 21 and a portion of the underlying third-layer dielectric film 20 by using an anisotropic etching technique to obtain the structure shown in FIG. 2D. The etching system used in the anisotropic etching process is a two-frequency reactive-ion-etching (RIE) system wherein both the upper electrode overlying the semiconductor wafer and the lower electrode mounting thereon the wafer are applied with respective RF powers. The etching gas includes C₅F₈, O₂ and Ar, which are introduced at flow rates of 30 standard-cubic-centimeters per minute (sccm), 50 sccm and 400 sccm, respectively, at a total pressure 25 mTorr. The reason for employing C₅F₈ is that this carbon-rich fluorocarbon gas is expected to improve the etch selectivity of the patterned film with respect to the resist mask pattern. The RF power applied to the upper electrode in the etching system is 2500 watts, whereas the RF power applied to the lower electrode in the etching system is 3000 watts. These etching conditions provide taper-less contact holes.

The above etching conditions provide an etch selectivity of around 5 for the anti-reflection film 21 with respect to the resist mask pattern 22. This range of etch selectivity may take a considerable time length for etching the anti-reflection film 21, and thus, the etching of the anti-reflection film 21 may use an increased flow rate for the O₂ and additional CF₄ in the mixed gas, if necessary. This etching is stopped at a height of 501 nm above the top of the interconnect lines 19, or at an etching depth of 150 nm in the third-layer dielectric film 20, thereby preventing the etching from reaching the surface of the interconnect lines 19

Thereafter, as shown in FIG. 2E, a specific film 23 is deposited on the entire surface, the specific film 23 containing carbon and hydrogen as main components thereof, which are similar to those of the photoresist mask pattern 22. The process conditions of deposition of the specific film 23 are such that the flow rates of CH₃F and Ar are 30 sccm and 400 sccm, respectively, the ambient pressure is 25 mTorr, and the RF powers applied to the upper electrode and lower electrode are 2500 watts and 500 watts, respectively. These deposition conditions provide a deposition rate of around 30 nm/minutes, which may be controlled by the control of gas composition, flow rate and applied RF powers. It was found that a sample of the specific film 23 deposited using the above process conditions reduced the diameter of top opening of the contact holes by around 50 nm.

The specific film 23 is then selectively etched using a second anisotropic dry etching step, as shown in FIG. 2F. The second anisotropic dry etching uses O₂-containing gas and etches the specific film 23 on top of the photoresist mask pattern 22 and the bottom of the contact holes. A typical example of this anisotropic dry etching process uses flow rates of 70 sccm for CF₄, 30 sccm for O₂, and 750 sccm for Ar, an ambient pressure of 25 mTorr, and RF powers of 3000 watts for the upper electrode and 1000 watts for the lower electrode. Under these conditions, the portion of the specific film 23 on the bottom of the contact holes can be removed in is a treatment time of around 10 seconds.

Subsequently, as shown in FIG. 2G, the portion of the third-layer dielectric film 20 and second-layer dielectric film 18 remaining below the bottom of the contact holes is etched using a third anisotropic dry etching step, thereby exposing the top of the first contact plugs 17 from the bottom of the contact holes.

In the third anisotropic dry etching step, etching conditions similar to those of the first anisotropic dry etching step may be used, thereby obtaining a higher etch selectivity of the dielectric films 18, 20 with respect to the specific film 23. Thereafter, an ashing treatment and a cleaning process are performed to remove the photoresist mask pattern 22 and the specific film 23, to thereby obtain the structure of FIG. 2H.

In FIG. 2H, the top portion of the second contact holes has a diameter of 150 nm, whereas the bottom portion of the second contact holes has a diameter of 100 nm. The top portion of the 150 nm diameter assures a larger margin for the alignment with respect to the overlying interconnect lines, and the bottom portion of the 100 nm diameter assures the clearance with respect to the interconnect lines 19 through which the contact holes pass while being insulated therefrom.

As described above, the process of the present embodiment uses a single dry etching chamber, in which the first anisotropic dry etching step, deposition step of the specific film, second anisotropic etching step, and third anisotropic etching process are consecutively performed. The first anisotropic dry etching process uses carbon-rich gas such as C₄F₈, C₅F₈, C₄F₆, a higher etch selectivity of the dielectric film with respect to the photoresist mask pattern, a taper-less etching condition, wherein the etching does not reach top of the interconnect lines.

The specific film deposition step uses hydrogen-containing gas such as a gas selected from the group consisting of a mixed gas including CF₄ and H₂, a CH₃F gas and a CH₂F₂ gas The second anisotropic dry etching process may use O₂-containing gas, and removes the specific film at the bottom of the contact holes. The third anisotropic dry etching process may use a mixed gas similar to the mixed gas used in the first anisotropic dry etching process, and should use a higher etch selectivity of the dielectric film with respect to the specified film, and a taper-less condition.

In the first and third anisotropic dry etching steps of the above process, use of the carbon-rich gas such as C₄F₈, C₅F₈ and C₄F₆, which are richer than CF₄ in the carbon content, provides a higher etch selectivity of the interlayer dielectric film with respect to the photoresist film such as KrF resist film and ArF resist film. This prevents the contact holes from having a larger diameter of the top opening thereof, or a distorted sectional structure thereof. The taper-less etching condition prevents an unstable etching such as an etch stop failure.

In the above embodiment, the first and third anisotropic dry etching processes used C₅F₈; however, other carbon-rich fluorocarbon gas such as C₄F₈ and C₄F₆ may be used to obtain a higher etch selectivity with respect to the resist film and to provide a taper-less etching. Although the specific film deposition step used CH₃F, other gas such as a mixture of CF₄ and H₂, or CH₂F₂ may be used for depositing the specific film.

The exemplified process is used for forming a contact hole exposing the top of a contact plug; however, the contact hole formed by the present invention is not limited to such a contact hole, and may be such that formed on a diffused region.

In the above embodiment, a 200-nm-thick silicon oxide film 20 is formed on the interconnect lines 19, and etched by the first anisotropic dry etching step to a depth of 150 nm, to leave a portion of the silicon oxide film 20 having a thickness of 50 nm on the interconnect line 19, to thereby form a first contact hole. For improving the etch uniformity in the first anisotropic dry etching step, another film having a different material such as silicon nitride and a thickness of 10 nm, for example, may be formed in advance at a specified height above the top of the interconnect lines 19. In other words, the third-layer dielectric film 20 may have a three-layer structure including a 50-nm-thick silicon oxide layer, a 10-nm-thick silicon nitride layer and a 150-nm-thick silicon oxide layer, consecutively as viewed from the top of the interconnect lines 19, and the first anisotropic etching is stopped at the depth of the silicon nitride film.

Since the above embodiments are described only for examples, the present invention is not limited to the above embodiments and various modifications or alterations can be easily made therefrom by those skilled in the art without departing from the scope of the present invention.

What is claimed is:

1. A method for manufacturing a semiconductor device comprising:
forming a dielectric film on an underlying structure including a semiconductor substrate;
etching said dielectric film in a first anisotropic dry etching step using a first gas including rare gas, oxygen gas and carbon-rich gas, which is richer than CF₄ in carbon content, and a photoresist mask as an etching mask to a specified depth of said dielectric film, to thereby form a first contact hole in said dielectric film;
depositing a specific film at least within said first contact hole by using a second gas as a source gas;
etching a first potion of said specific film on a bottom of said first contact hole selectively from a second portion of said specific film on a sidewall thereof in a second anisotropic dry etching step using a third gas as an etching gas, to expose said dielectric film through said bottom of said first contact hole;
etching said dielectric film exposed from said bottom of said first contact hole in a third anisotropic dry etching step using a fourth gas as an etching gas and said second portion of said specific film as an etching mask, to form a second contact hole extending stepwise from said first contact hole and exposing therefrom said underlying structure; and
removing said second portion of said specific film on said sidewall of said first contact hole.

2. The method according to claim 1, wherein said first gas includes a gas selected from the group consisting of fluorocarbons C₄F₈, C₅F₈, C₄F₆ and any gas which is richer than these fluorocarbons in carbon content.

3. The method according to claim 1, wherein said fourth gas has a composition substantially same as a composition of said first gas.

4. The method according claim 1, wherein said second gas is selected from the group consisting of a mixed gas including CF₄ and H₂, a CH₃F gas and a CH₂F₂ gas.

5. The method according to claim 1, Wherein said third gas includes O₂.

6. The method according to claim 1, wherein each of said first and second contact holes has substantially no tapered portion.

7. The method according to claim 1, wherein said underlying structure includes a contact plug aligned with said second contact hole as viewed normal to said semiconductor substrate, an insulating film embedding said contact plug, interconnect lines embedded by said insulating film, said second contact hole is not aligned with any of said interconnect lines as viewed normal to said semiconductor substrate.

8. The method according to claim 1, wherein said underlying structure includes a diffused region.

9. The method according to claim 1, wherein said photoresist mask includes KrF resist or ArF resist.

10. The method according to claim 1, wherein the steps of said etching and forming are performed in a single chamber without exposing said semiconductor device to atmospheric air.

11. The method according to claim 1, wherein said dielectric film is a silicon oxide film.

12. The method according to claim 1, wherein said dielectric film consecutively includes a first silicon oxide film, a silicon nitride film and a second silicon oxide film, as viewed from said underlying structure, and said specified depth corresponds to a depth of said silicon nitride film.
